(19) United States
(12) Patent Application Publication
(10) Pub. No.: US 2007/0096338 A1
(43) Pub. Date: May 3, 2007

(54) Semiconductor package having non-solder mask defined bonding pads and solder mask defined bonding pads, printed circuit board and semiconductor module having the same

(75) Inventors: Shin Kim, Cheonan-si (KR); Se-Yong Oh, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/518,257

(22) Filed: Sep. 11, 2006

(30) Foreign Application Priority Data
Sep. 12, 2005 (KR) 2005-84562

(51) Int. Cl. H01L 23/48; H01L 23/52; H01L 29/40

(52) U.S. Cl. 257/780

(57) ABSTRACT

A semiconductor package may include a semiconductor chip and a substrate. The substrate may include a plurality of bonding pads for interfacing the semiconductor chip with a printed circuit board through conductive bumps that may be electrically connected to the bonding pads, respectively. The bonding pads may include non-solder mask defined (NSMD) bonding pads and solder mask defined (SMD) bonding pads that may be alternately arranged on the substrate. The SMD bonding pads may have sufficient reliability with respect to a drop test and the NSMD bonding pads may have sufficient reliability with respect to the board-level temperature cycle.

### PRIORITY STATEMENT

This application claims priority under 35 USC § 119 from Korean Patent Application No. 2005-84562, filed on Sep. 12, 2005, the contents of which are herein incorporated by reference in its entirety.

### BACKGROUND

1. Field of the Invention

Example embodiments of the present invention relate to a semiconductor package. More particularly, example embodiments the present invention relate to a ball grid array (BGA) semiconductor package.

2. Description of the Related Art

Chip scale packaging (CSP) may involve packing semiconductor chips into a package having a size substantially similar to or slightly larger than that of the manufactured semiconductor product.

A BGA semiconductor package among the CSP packages may be manufactured by a surface mount technology (SMT). The SMT may increase the number of input/output pins received in the semiconductor device to improve a mount density. That is, in the BGA package, a signal may be transmitted between the semiconductor chip and a printed circuit board (PCB) through a conductive bump that may be mounted on the BGA package so that the number of the input/output pins may be increased.

The BGA package may be employed in a memory such as (for example) a Rambus dynamic random access memory (DRAM) that may be used as a memory of a portable information communication device such as (for example) a mobile phone and a digital camera, a personal computer (PC), a laptop computer and/or a work station.

A plurality of conductive bumps may be used in a method of packaging a flip chip. Further, a bonding pad, which may be electrically connected to the conductive bump, may be classified as a solder mask defined (SMD) bonding pad and a non-solder mask defined (NSMD) bonding pad depending on the manner for defining a region on the bonding pad where the conductive bump may be received.

FIG. 1 is a cross-sectional view illustrating a conventional SMD bonding pad.

Referring to FIG. 1, a substrate 12 and a PCB 22 may be provided with an SMD bonding pad. The SMD bonding pad of the substrate 12 may correspond to a metal bonding pad 14 provided on the substrate 12. The substrate 12 may interconnect or interfaces the PCB 24 with a semiconductor chip (not shown). A solder mask 16 may be provided on the substrate 12 to partially cover the metal bonding pad 14. Thus, the metal bonding pad 14 may be partially exposed through the solder mask 16. A conductive bump 24 may be mounted on the metal bonding pad 14. A bonding pad 20 may be provided on the PCB 22. A solder mask 18 may be provided on the PCB 22 and may partially cover the bonding pad 20 to form the SMD bonding pad. Openings of the solder masks 16 and 18 may define contact regions of the bonding pads 14 and 20 that may be electrically connected to the conductive bump 24. The substrate 12 and the PCB 22 may be electrically connected to each other through the conductive bump 24. The solder masks 16 and 18 may prevent a liquid solder from flowing toward undesired regions of the substrate 12 and/or the PCB 42, and may have influence on a configuration of the conductive bump 24 after a reflow process.

FIG. 2 is a cross-sectional view illustrating a conventional NSMD bonding pad.

Referring to FIG. 2, an NSMD bonding pad of a substrate 32 may include a metal bonding pad 34 on the substrate 32. A solder mask 36 may be provided on the substrate 32. The solder mask 36 may not make contact (nor overlap) with the bonding pad 34. A solder mask 38 may be provided on a PCB 42. The solder mask 38 may not make contact (nor overlap) with the bonding pad 40 of the PCB 42. Configurations and/or sizes of the bonding pads 34 and 40 may determine a configuration of a conductive bump 44 after a reflow process.

The SMD bonding pad may provide sufficient reliability with respect to a drop test. However, the SMD bonding pad may provide insufficient reliability with respect to a board-level temperature cycle.

In contrast, The NSMD bonding pad may have sufficient reliability with respect to the board-level temperature cycle. However, the NSMD bonding pad may provide insufficient reliability with respect to the drop test.

### SUMMARY

According to an example, non-limiting embodiment, a semiconductor package may include a semiconductor chip and a substrate that may include bonding pads that may be electrically connected to conductive bumps, respectively. The substrate may interface the semiconductor chip with a printed circuit board (PCB) through the conductive bumps. The bonding pads may include non-solder mask defined (NSMD) bonding pads and solder mask defined (SMD) bonding pads that may be alternately arranged on the substrate.

According to another example, non-limiting embodiment, the semiconductor package may include first NSMD bonding pads that may be arranged on a central portion of the substrate, and second NSMD bonding pads and SMD bonding pads that may be alternately arranged on a peripheral portion of the substrate.

According to another example, non-limiting embodiment, a printed circuit board (PCB) may include a board. Non-solder mask defined (NSMD) bonding pads and solder mask defined (SMD) bonding pads may be alternately arranged on the board.

According to another example, non-limiting embodiment, a semiconductor module may include a PCB. A semiconductor package may include a semiconductor chip and a substrate that may include second NSMD bonding pads and second SMD bonding pads that may be alternately arranged on the substrate. The substrate may interface the semiconductor chip with the PCB through conductive bumps that may be electrically connected to NSMD bonding pads of the PCB and the second NSMD bonding pads, and SMD bonding pads of the PCB and the second SMD bonding pads, respectively.

According to another example, non-limiting embodiment, a semiconductor module may include a PCB. A semiconductor package may include a semiconductor chip and a substrate that may include second NSMD bonding pads that may be arranged on a central portion of the substrate, and third NSMD bonding pads and second SMD bonding pads that may be alternately arranged on a peripheral portion of the substrate. The substrate may interface the semiconductor chip with the PCB through conductive bumps that may be electrically connected to NSMD bonding pads of the PCB, the second NSMD bonding pads and the third NSMD bonding pads, and SMD bonding pads of the PCB and the second SMD bonding pads, respectively.

### BRIEF DESCRIPTION OF THE DRAWINGS

Example, non-limiting embodiments of the invention will be described with the accompanying drawings.

FIG. 1 is a cross-sectional view illustrating a conventional SMD bonding pad.

FIG. 2 is a cross-sectional view illustrating a conventional NSMD bonding pad.

FIG. 3 is a cross-sectional view illustrating a semiconductor package having an arrangement of SMD bonding pads and NSMD bonding pads in accordance with an example, non-limiting embodiment of the present invention.

FIG. 4 is a cross-sectional view illustrating a semiconductor module having an arrangement of SMD bonding pads and NSMD bonding pads in accordance with another example, non-limiting embodiment of the present invention.

FIGS. 5A and 5B are cross-sectional views illustrating a semiconductor package or a printed circuit board including SMD bonding pads and NSMD bonding pads alternately arranged in accordance with another example, non-limiting embodiment of the present invention.

FIGS. 6A and 6B are cross-sectional views illustrating a semiconductor package or a printed circuit board including SMD bonding pads and NSMD bonding pads alternately arranged in a column direction in accordance with another example, non-limiting embodiment of the present invention.

FIGS. 7A and 7B are cross-sectional views illustrating a semiconductor package or a printed circuit board including SMD bonding pads and NSMD bonding pads alternately arranged in a row direction in accordance with another example, non-limiting embodiment of the present invention.

FIG. 8 is a cross-sectional view illustrating a semiconductor package or a printed circuit board having an arrangement of SMD bonding pads and NSMD bonding pads in accordance with another example, non-limiting embodiment of the present invention.

FIGS. 9A and 9B are cross-sectional views illustrating a semiconductor package or a printed circuit board including SMD bonding pads and NSMD bonding pads alternately arranged in a column direction in accordance with another example, non-limiting embodiment of the present invention.

FIGS. 10A and 10B are cross-sectional views illustrating a semiconductor package or a printed circuit board including SMD bonding pads and NSMD bonding pads alternately arranged in a row direction in accordance with another example, non-limiting embodiment of the present invention.

FIGS. 11 to 14 are cross-sectional views illustrating a semiconductor package or a printed circuit board including SMD bonding pads and NSMD bonding pads in accordance with another example, non-limiting embodiment of the present invention.

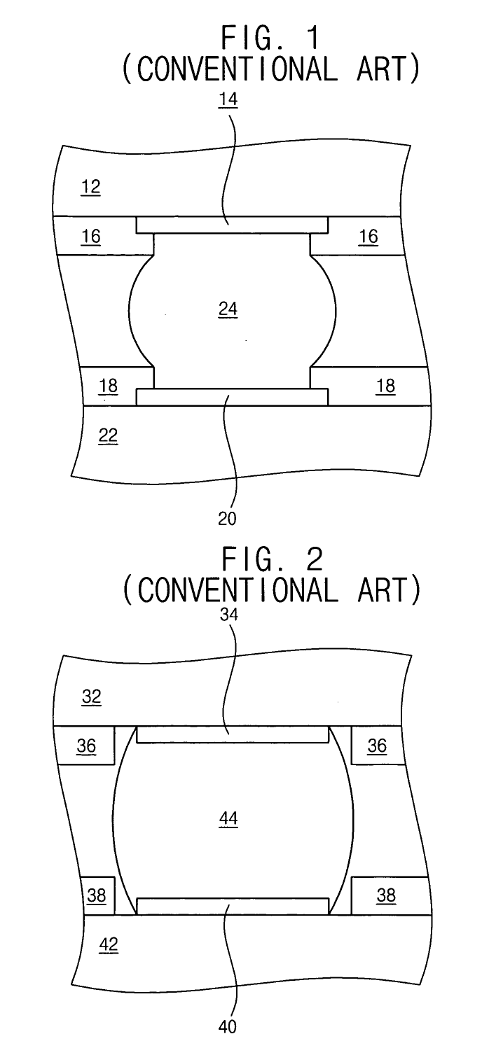

### DESCRIPTION OF EXAMPLE, NON-LIMITING EMBODIMENTS

Example, non-limiting embodiments of the present invention are described with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. The drawings are not to scale. Like reference numerals refer to like elements throughout.

It will be understood that when an element or layer is referred to as being “on,” “connected to” and/or “coupled to” another element or layer, it can be directly on, connected and/or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” includes any and all combinations of one or more of the associated listed items.

Although the terms first, second, etc. may be used to describe various elements, components, regions, layers and/or sections, these elements, components, regions, layers and/or sections should not be limited by these terms. These terms may be used to distinguish one element, component, region, layer or section from another element, component, region, layer or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like, may be used herein for ease of description to describe one element and/or feature's relationship to another element(s) and/or feature(s), for example, as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements and/or features. The device may be otherwise oriented (rotated 90 degrees or at other orientations) and the spatially relative descriptors used herein interpreted accordingly.

The terminology used herein is for the purpose of describing example embodiments only and is not intended to be limiting of the invention. As used herein, the singular terms “a,” “an” and “the” are intended to include the plural forms as well, unless the context clearly indicates otherwise. It will be understood that the terms “includes” and/or “including” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

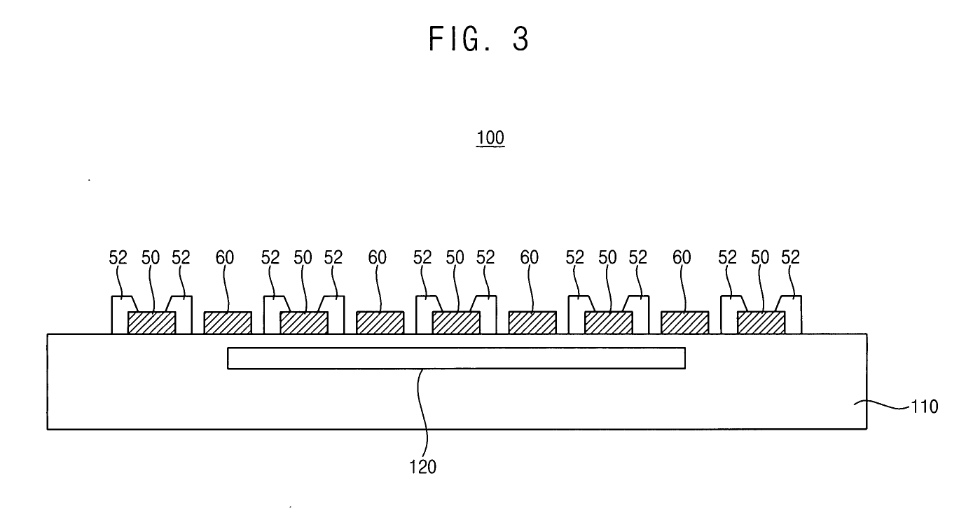

FIG. 3 is a cross-sectional view illustrating a semiconductor package having an arrangement of SMD bonding pads and NSMD bonding pads in accordance with an example, non-limiting embodiment of the present invention.

Referring to FIG. 3, the semiconductor package 100 may include a semiconductor chip 120 mounted on a substrate 110. The semiconductor chip 120 may be electrically connected to the substrate 110 by a wire bonding process and/or a bump process, for example.

The substrate 110 may interface the semiconductor chip 120 with a printed circuit board (PCB) (not shown).

After the semiconductor chip 120 is mounted on the substrate 110, a mold compound encapsulation material may encapsulate a surface of the substrate 110 and the semiconductor chip 120.

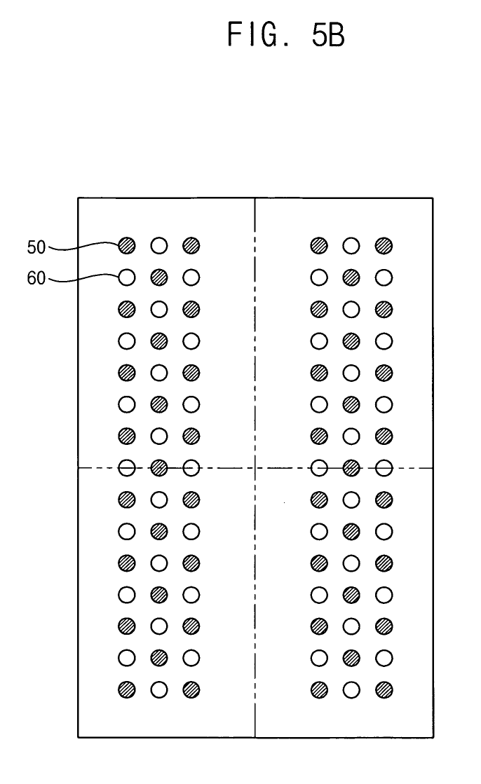

SMD bonding pads 50 and NSMD bonding pads 60 may be arranged on the substrate 110. For example, the SMD bonding pads 50 and the NSMD bonding pads 60 may be alternately arranged in a matrix pattern. Alternatively, the SMD bonding pads 50 and the NSMD bonding pads 60 may be alternately arranged in a row direction or a column direction. Further, the NSMD bonding pads 60 may be arranged on a central portion of the substrate 110. The SMD bonding pads 50 may be arranged on a peripheral portion of the substrate 110. Numerous and varied arrangements of the SMD bonding pads 50 and the NSMD bonding pads 60 will be illustrated with reference to FIGS. 5A to 14.

The SMD bonding pads 50 and the NSMD bonding pads 60 may function to provide an electrical connection between the PCB (not shown in FIG. 3) and the substrate 110 via conductive bumps (not shown in FIG. 3). By way of example only, the conductive bump may be in the form of a solder ball.

A solder mask 52 may be provided on the substrate 110. The solder mask 52 may partially cover the SMD bonding pads 50. Each of the SMD bonding pads 50 may be partially exposed through an opening of the solder mask 52. A size of the opening of the solder mask 52 may be smaller than a size of the SMD bonding pad 50. A region of the SMD bonding pad 50 exposed through the solder mask 52 may define a contact region between the SMD bonding pad 50 and the conductive bump.

The solder mask 52 may not make contact with (and is not overlapped with) the NSMD bonding pad 60. Thus, an edge of the NSMD bonding pad 60 may be exposed.

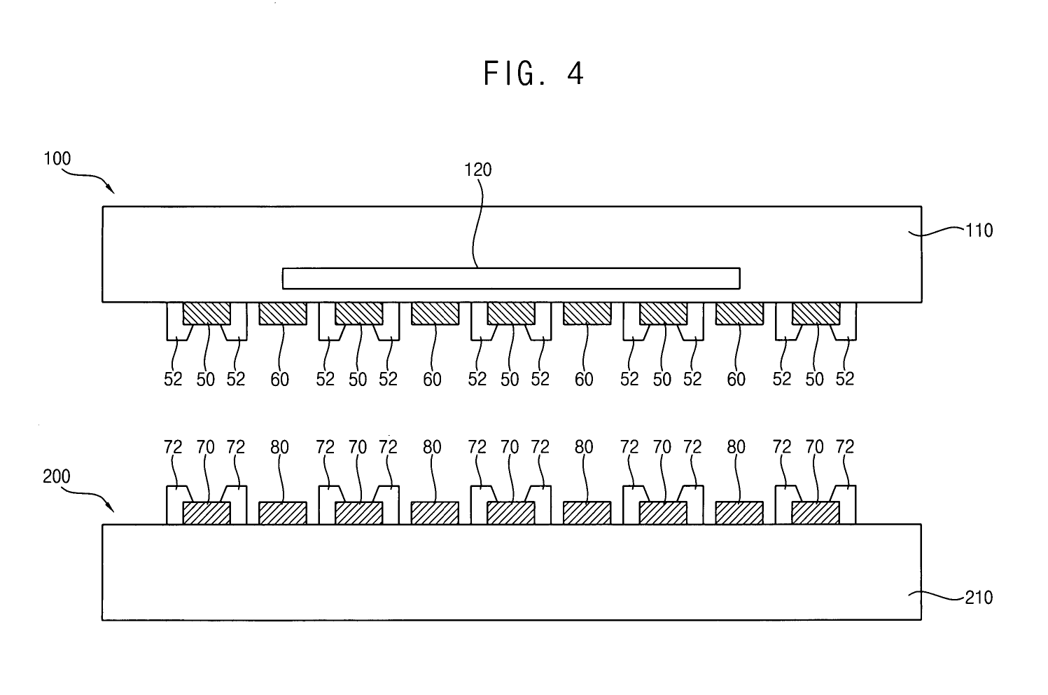

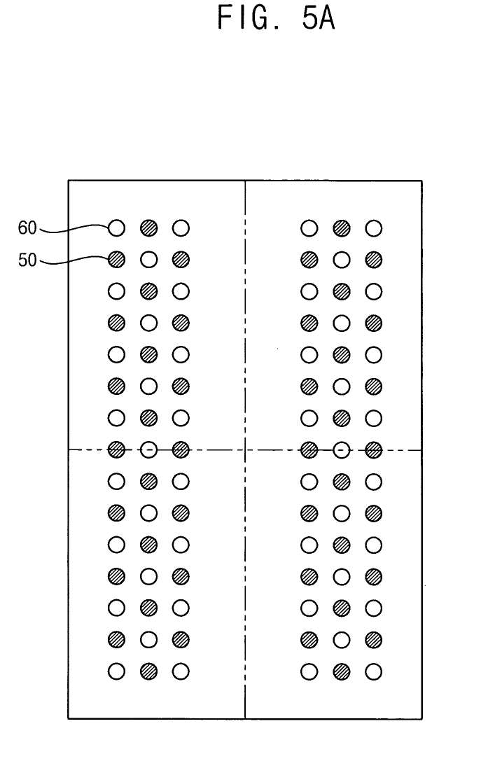

FIG. 4 is a cross-sectional view illustrating a semiconductor module having an arrangement of SMD bonding pads and NSMD bonding pads in accordance with another example, non-limiting embodiment of the present invention.

Referring to FIG. 4, the semiconductor module may include the semiconductor package 100 (as shown in FIG. 3, for example) and a PCB 200.

The PCB 200 may include a board 210 on which a solder mask 72, SMD bonding pads 70 and NSMD bonding pads 80 may be provided. The SMD bonding pads 70 and the NSMD bonding pads 80 may be arranged on the board 210.

The PCB 200 may be interfaced with the semiconductor chip 120 through the conductive bumps that may be electrically connected to the SMD bonding pads 50 and 70 and the NSMD bonding pads 60 and 80, respectively.

The arrangements of the SMD bonding pads 70 and the NSMD bonding pads 80 of the PCB 200 may be substantially the same as or different from those of the SMD bonding pads 50 and the NSMD bonding pads 60 of the semiconductor package 100.

For example, the SMD bonding pads 50 and the NSMD bonding pads 60 of the semiconductor package 100 may be alternately arranged on the substrate 110 in the row direction (and/or the column direction), and the SMD bonding pads 70 and the NSMD bonding pads 80 of the PCB 200 may be alternately arranged on the board 210 in a direction substantially the same as the row direction (and/or the column direction). In contrast, the SMD bonding pads 50 and the NSMD bonding pads 60 of the semiconductor package 100 may be alternately arranged on the substrate 110 in the row direction (and/or the column direction), and the SMD bonding pads 70 and the NSMD bonding pads 80 of the PCB 200 may be alternately arranged on the board 210 in a direction substantially perpendicular to the row direction (and/or the column direction). That is, an SMD bonding pad of the semiconductor package may cooperate with an NSMD bonding pad of the semiconductor package, and vice versa.

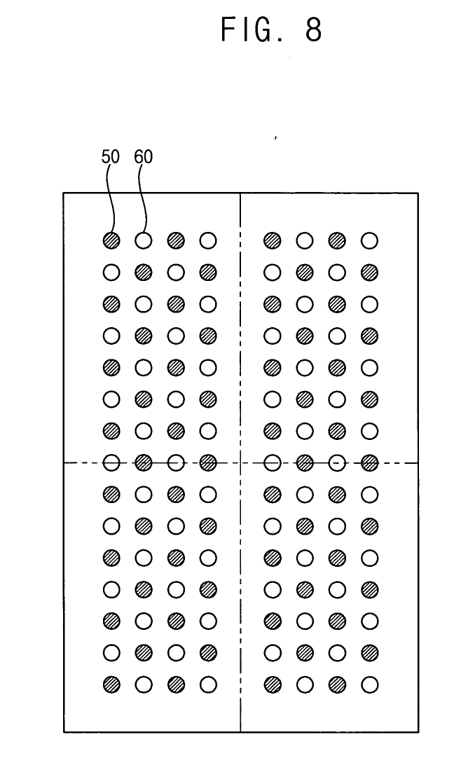

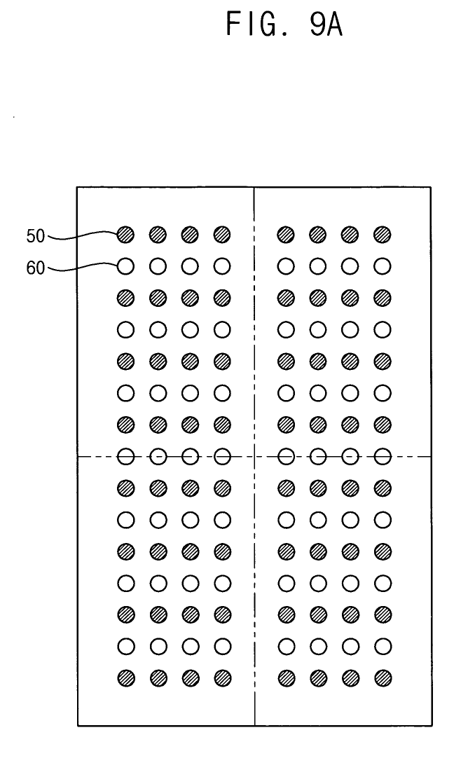

FIGS. 5A to 10B are cross-sectional views illustrating a semiconductor package (or a printed circuit board) including SMD bonding pads and NSMD bonding pads alternately arranged in the row direction and/or the column direction in accordance with another example, non-limiting embodiment of the present invention. In FIGS. 5A to 7B, a pair of bonding pad arrays may include three columns of the bond pads. In FIGS. 8 to 10B, a pair of bonding pad arrays may include four columns of the bonding pads. In alternative embodiments, the bonding pad arrays may include more or less columns of the bonding pads.

The SMD bonding pads 50, which may provide sufficient reliability with respect to the drop test, and the NSMD bonding pads 60, which may provide sufficient reliability with respect to the board-level temperature cycle, may be alternately arranged on the substrate 110 of the semiconductor package 100. Thus, as compared to conventional structures, the semiconductor package 100 and the PCB 200 may have improved reliabilities with respect to the drop test and the board-level temperature cycle, for example.

Referring to FIGS. 5A, 5B and 8, the SMD bonding pads 50 and the NSMD bonding pads 60 may be alternately arranged on the semiconductor package (or the PCB) in the row direction and the column direction. Thus, the number of the SMD bonding pads 50 may be about the same as that of the NSMD bonding pads 60.

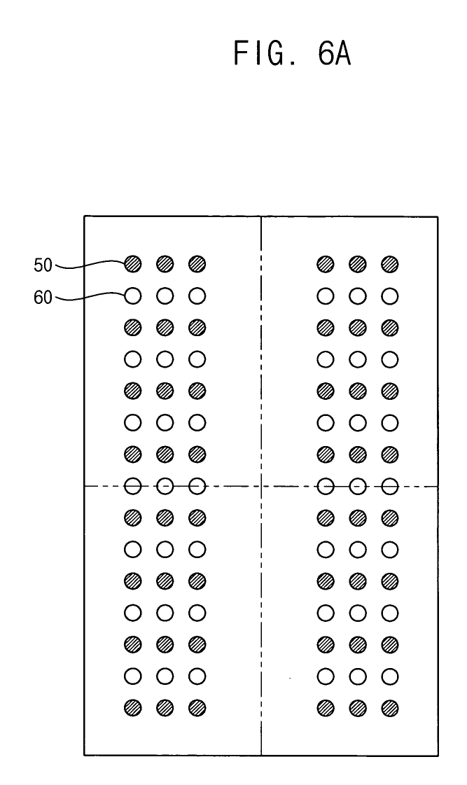

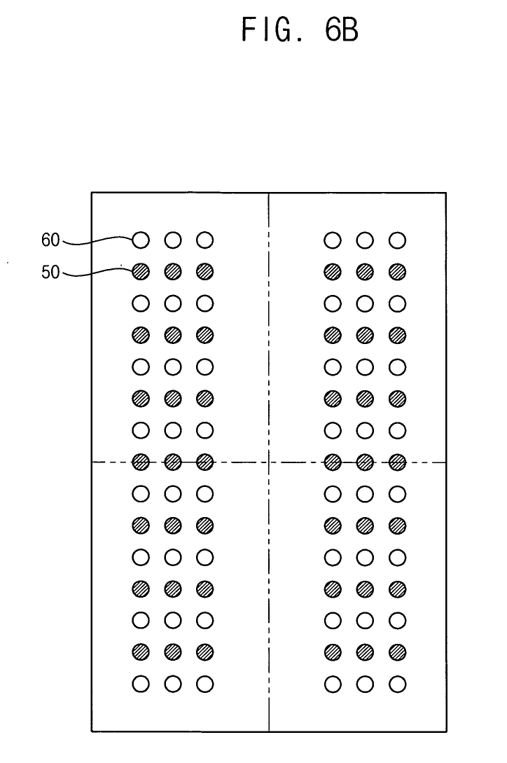

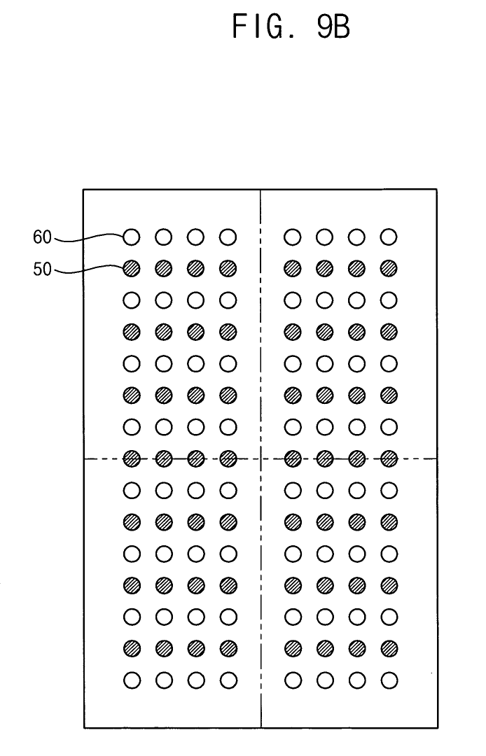

Referring to FIGS. 6A, 6B, 9A and 9B the SMD bonding pads 50 and the NSMD bonding pads 60 may be alternately arranged on the semiconductor package (or the PCB) in the column direction. Thus, the number of the SMD bonding pads 50 may be about the same as that of the NSMD bonding pads 60.

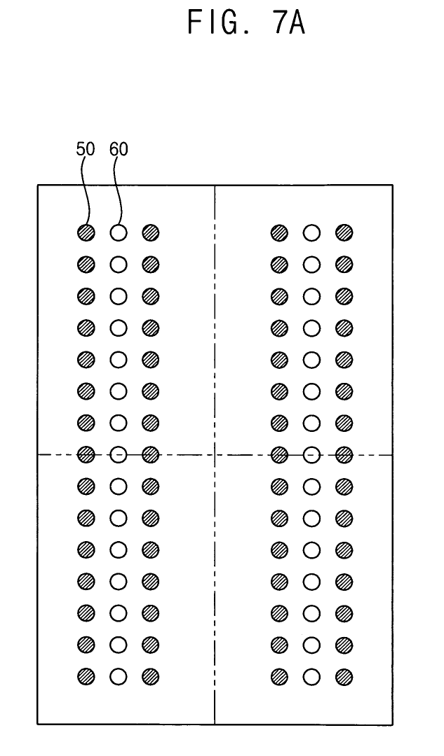

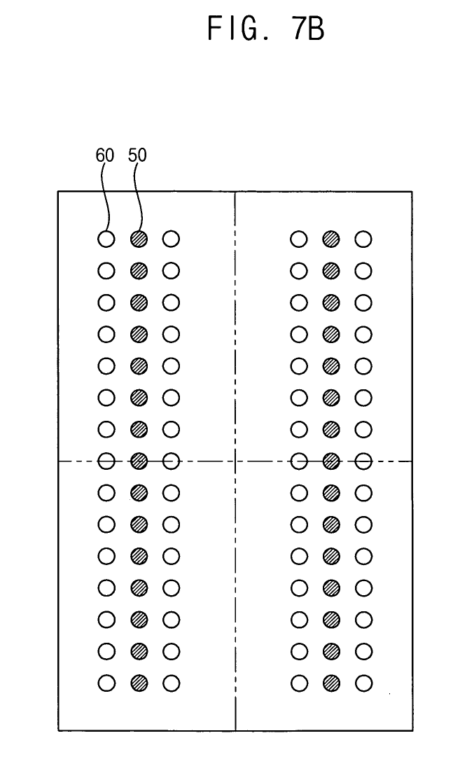

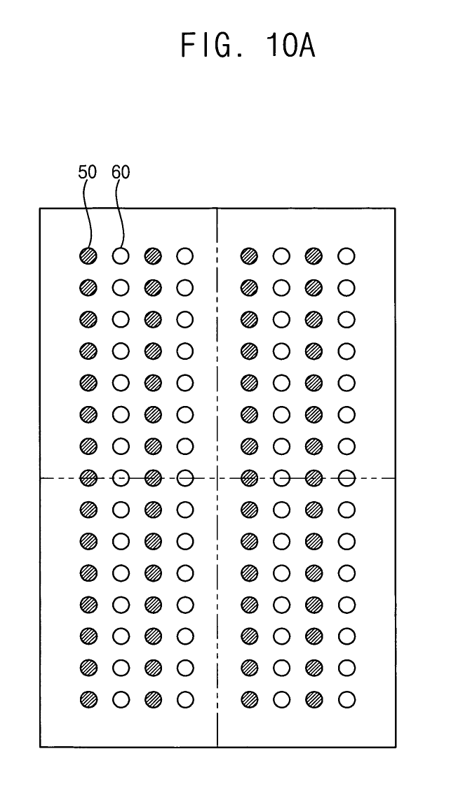

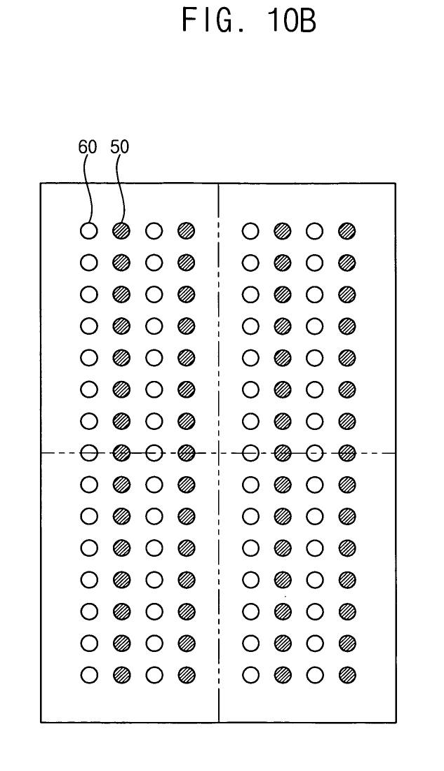

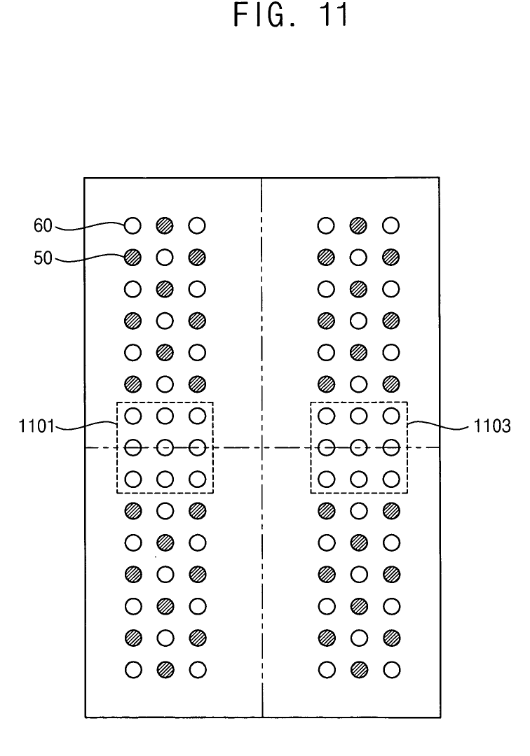

Referring to FIGS. 7A, 7B, 10A and 10B, the SMD bonding pads 50 and the NSMD bonding pads 60 may be alternately arranged on the semiconductor package (or the PCB) in the row direction. In FIGS. 10A and 10B, the number of the SMD bonding pads 50 may be about the same as that of the NSMD bonding pads 60. That is, a ratio between the numbers of the SMD bonding pads 50 and the NSMD bonding pads 60 may be about 1:1. In FIG. 7B, the number of the NSMD bonding pads 60 may be about two times larger than that of the SMD bonding pads 50. That is, a ratio between the numbers of the SMD bonding pads 50 and the NSMD bonding pads 60 may be about 1:2 (or about 2:1, as shown in FIG. 7A). In alternative embodiments, the ratio between the numbers of the SMD bonding pads 50 and the NSMD bonding pads 60 may be varied.

Referring to FIGS. 11 to 14, the NSMD bonding pads 60 may be arranged on central portions 1101 and 1103 of the substrate 110 (or the board 210). The SMD bonding pads 50 and the NSMD bonding pads 60 may be alternately arranged on the peripheral portion of the substrate 110 (or the board 210) in the row direction and/or the column direction. Thus, as compared to conventional structures, the semiconductor package 100 and the PCB 200 may have improved reliabilities with respect to the drop test and the board-level temperature cycle, for example.

Referring to FIG. 11, the NSMD bonding pads 60 may be arranged on the central portions 1101 and 1103 of the substrate 110 (or the board 210). The SMD bonding pads 50 and the NSMD bonding pads 60 may be alternately arranged on the peripheral portion of the substrate 110 (or the board 210) in the row direction and the column direction.

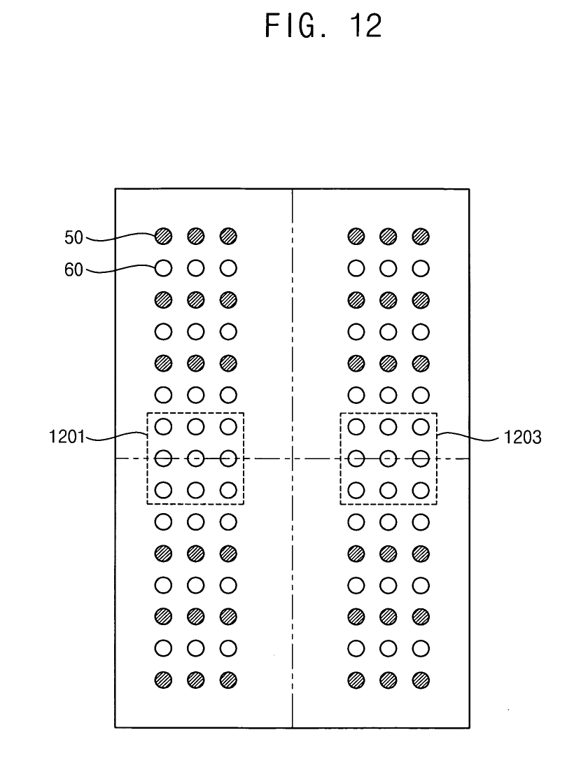

Referring to FIG. 12, the NSMD bonding pads 60 may be arranged on the central portions 1201 and 1203 of the substrate 110 (or the board 210). The SMD bonding pads 50 and the NSMD bonding pads 60 may be alternately arranged on the peripheral portion of the substrate 110 (or the board 210) in the column direction. Here, the SMD bonding pads 50 and the NSMD bonding pads 60 on the peripheral region of the substrate 110 (or the board 210) may be replaced with each other.

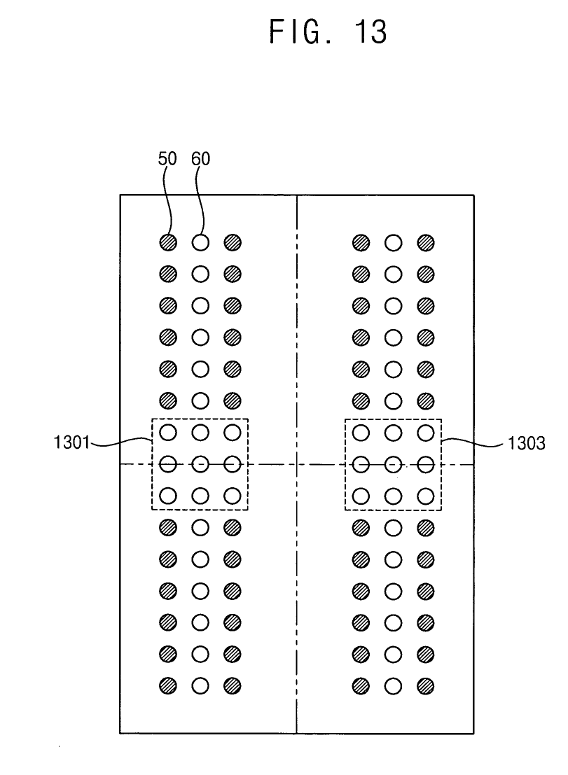

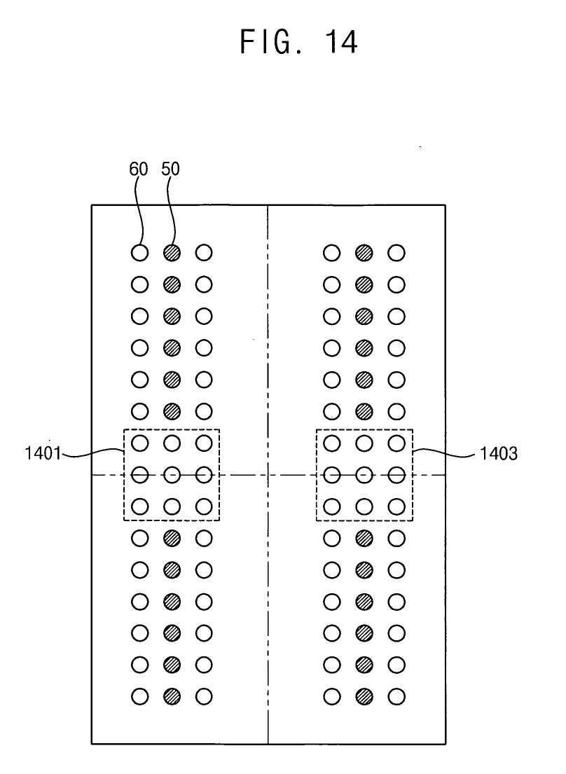

Referring to FIG. 13, the NSMD bonding pads 60 may be arranged on the central portions 1301 and 1303 of the substrate 110 (or the board 210). The SMD bonding pads 50 and the NSMD bonding pads 60 may be alternately arranged on the peripheral portion of the substrate 110 (or the board 210) in the row direction. As shown in FIG. 14, the SMD bonding pads 50 and the NSMD bonding pads 60 on the peripheral region of the substrate 110 (or the board 210) may be replaced with each other.

In the example, non-limiting embodiments, the arrangements of the SMD bonding pads and the NSMD bonding pads may vary in accordance with configurations of the semiconductor package and/or other conditions.

According to example, non-limiting embodiments of the present invention, the NSMD bonding pads, which may have insufficient reliability with respect to the drop test, and the SMD bonding pads, which may have sufficient reliability with respect to the drop test, may be alternately arranged on the substrate of the semiconductor package and/or the board of the PCB. Thus, as compared to conventional structures, the semiconductor package 100 and the PCB 200 may have improved reliability with respect to the drop test. Further, the SMD bonding pads, which may have insufficient reliability with respect to the board-level temperature cycle, and the NSMD bonding pads, which may have sufficient reliability with respect to the board-level temperature cycle, may be alternately arranged on the substrate of the semiconductor package and/or the board of the PCB. Thus, as compared to conventional structures, the semiconductor package 100 and the PCB 200 may have improved reliabilities with respect to the board-level temperature cycle.

The SMD bonding pads may have sufficient reliability with respect to the drop test and the NSMD bonding pads may have sufficient reliability with respect to the board-level temperature cycle may be alternately arranged on the semiconductor package and/or the PCB. Thus, as compared to conventional structures, the semiconductor package and the PCB may have improved reliabilities with respect to the drop test and the board-level temperature cycle, for example.

Having described example, non-limiting embodiments of the present invention, numerous modifications and variations may become apparent to persons skilled in the art. It will be understood that changes may be suitably implemented in the disclosed embodiments, and that such changes still fall within the spirit and scope of the invention defined by the appended claims.

What is claimed is:

1. A semiconductor package comprising:
a semiconductor chip; and
a substrate including bonding pads that are electrically connected to conductive bumps, respectively, the substrate interfacing the semiconductor chip with a printed circuit board (PCB) through the conductive bumps,
wherein the bonding pads include non-solder mask defined (NSMD) bonding pads and solder mask defined (SMD) bonding pads alternately arranged on the substrate.

2. The semiconductor package of claim 1, wherein the NSMD bonding pads and the SMD bonding pads are alternately arranged on the substrate in a row direction.

3. The semiconductor package of claim 1, wherein the NSMD bonding pads and the SMD bonding pads are alternately arranged on the substrate in a column direction.

4. The semiconductor package of claim 3, wherein a ratio between the numbers of the SMD bonding pads and the NSMD bonding pads is about 1:2 or about 2:1.

5. The semiconductor package of claim 3, wherein a ratio between the numbers of the SMD bonding pads and the NSMD bonding pads is about 1:1.

6. The semiconductor package of claim 1, wherein first NSMD bonding pads are arranged on a central portion of the substrate, and
wherein second NSMD bonding pads and SMD bonding pads are alternately arranged on a peripheral portion of the substrate.

7. The semiconductor package of claim 6, wherein the second NSMD bonding pads and the SMD bonding pads are alternately arranged on the substrate in a row direction.

8. The semiconductor package of claim 6, wherein the second NSMD bonding pads and the SMD bonding pads are alternately arranged on the substrate in a column direction.

9. A printed circuit board (PCB) comprising:
a board; and
non-solder mask defined (NSMD) bonding pads and solder mask defined (SMD) bonding pads alternately arranged on the board.

10. The PCB of claim 9, wherein the NSMD bonding pads and the SMD bonding pads are alternately arranged on the substrate in a row direction.

11. The PCB of claim 9, wherein the NSMD bonding pads and the SMD bonding pads are alternately arranged on the substrate in a column direction.

12. A semiconductor module comprising:
a PCB according to claim 9; and
a semiconductor package including a semiconductor chip and a substrate that includes second NSMD bonding pads and second SMD bonding pads alternately arranged on the substrate,
the substrate interfacing the semiconductor chip with the PCB through conductive bumps electrically connected to the NSMD bonding pads of the PCB and the second NSMD bonding pads, and the SMD bonding pads of the PCB and the second SMD bonding pads, respectively.

13. The semiconductor module of claim 12, wherein the second NSMD bonding pads and the second SMD bonding pads are alternately arranged on the substrate in a row direction.

14. The semiconductor module of claim 13, wherein the NSMD bonding pads and the SMD bonding pads of the PCB are alternately arranged on the board in a row direction.

15. The semiconductor module of claim 13, wherein the NSMD bonding pads and the SMD bonding pads of the PCB are alternately arranged on the board in a column direction.

16. The semiconductor module of claim 12, wherein the second NSMD bonding pads and the second SMD bonding pads are alternately arranged on the substrate in a column direction.

17. A semiconductor module comprising:
a PCB according to claim 9; and
a semiconductor package including a semiconductor chip and a substrate that includes second NSMD bonding pads arranged on a central portion of the substrate, and third NSMD bonding pads and second SMD bonding pads alternately arranged on a peripheral portion of the substrate,
the substrate interfacing the semiconductor chip with the PCB through conductive bumps electrically connected to the NSMD bonding pads of the PCB, the second NSMD bonding pads and the third NSMD bonding pads, and the SMD bonding pads of the PCB and the second SMD bonding pads, respectively.

18. The semiconductor module of claim 17, wherein the third NSMD bonding pads and the second SMD bonding pads are alternately arranged on the substrate in a row direction.

19. The semiconductor module of claim 17, wherein the third NSMD bonding pads and the second SMD bonding pads are alternately arranged on the substrate in a column direction.
